(19) United States
(12) Patent Application Publication
(10) Pub. No.: US 2025/0359062 A1
(43) Pub. Date: Nov. 20, 2025

(54) SEMICONDUCTOR DEVICE

(71) Applicant: Samsung Electronics Co., Ltd., Suwon-si (KR)

(72) Inventors: HAKSEON KIM, Suwon-si (KR); SEJUN PARK, Suwon-si (KR); SEA HOON LEE, Suwon-si (KR); SEONGPIL CHANG, Suwon-si (KR)

(21) Appl. No.: 19/016,456

(22) Filed: Jan. 10, 2025

(30) Foreign Application Priority Data
May 17, 2024 (KR) 10-2024-0064393

(51) Int. Cl. H10B 43/40; H10B 41/40

(52) U.S. Cl. CPC H10B 43/40; H10B 41/40

(57) ABSTRACT

A semiconductor device includes a first peripheral circuit area, a second peripheral circuit area disposed on the first peripheral circuit area, and a cell area disposed on the second peripheral circuit area. The second peripheral circuit area includes a second substrate, a first layer disposed under the second substrate, the first layer including at least one, or a combination, of high density plasma oxide or tetraethoxysilane, a second layer disposed under the first layer, the second layer including at least one, or a combination, of silicon nitride, zirconium oxide, or aluminum oxide, and a through via penetrating through the second layer, the first layer, and the second substrate.

### CROSS-REFERENCE TO RELATED APPLICATION

This application claims the benefit of priority under 35 U.S.C. § 119 to Korean Patent Application No. 10-2024-0064393 filed on May 17, 2024, in the Korean Intellectual Property Office, the entire disclosure of which is incorporated herein by reference for all purposes.

### BACKGROUND

The disclosure relates to a semiconductor device. To reduce the size of semiconductor devices, semiconductor devices with vertically stacked device areas are being developed. One aspect of the disclosure may provide a semiconductor device with improved leakage current characteristics.

### SUMMARY

According to an aspect, there is provided a semiconductor device including a first peripheral circuit area, the first peripheral circuit area including a first substrate, a first bonding pad, and a first via electrically connecting the first substrate and the first bonding pad, a second peripheral circuit area disposed on the first peripheral circuit area, the second peripheral circuit area including a second substrate, a second bonding pad, a third bonding pad disposed opposite the second bonding pad, a first layer disposed under the second substrate, the first layer including at least one, or a combination, of high density plasma oxide or tetraethoxysilane, a second layer disposed under the first layer, the second layer including at least one, or a combination, of silicon nitride, zirconium oxide, or aluminum oxide, and a through via penetrating through the second layer, the first layer, and the second substrate and electrically connecting the second bonding pad and the third bonding pad, and a cell area disposed on the second peripheral circuit area.

According to an aspect, there is provided a method of manufacturing a semiconductor device, the method including providing a first wafer including a first peripheral circuit area and a second wafer including a second peripheral circuit area, wherein the first peripheral circuit area includes a first substrate, a first bonding pad, and a first via electrically connecting the first substrate and the first bonding pad, and the second peripheral circuit area includes a second substrate and a second bonding pad, providing a first layer disposed under the second substrate, the first layer including at least one, or a combination, of high density plasma oxide or tetraethoxysilane, and a second layer disposed under the first layer, the second layer including at least one, or a combination, of silicon nitride, zirconium oxide, or aluminum oxide, providing a third bonding pad opposite the second bonding pad in the second peripheral circuit area, bonding the first bonding pad and the third bonding pad, and providing a through via electrically connecting the second bonding pad and the third bonding pad, and bonding a third wafer including a cell area to the second peripheral circuit area.

Additional aspects of embodiments will be set forth in part in the description which follows and, in part, will be apparent from the description, or may be learned by practice of the disclosure.

Aspects of the embodiments may provide a semiconductor device in which transistor leakage current characteristics are improved. The effects of the semiconductor device according to embodiments are not limited to the above-mentioned effects, and other unmentioned effects can be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram of a semiconductor device;

FIG. 2 illustrates providing a first wafer including a first peripheral circuitry area as part of a method of manufacturing a semiconductor device;

FIG. 3 illustrates providing a second wafer including a second peripheral circuitry area as part of a method of manufacturing a semiconductor device;

FIG. 4 illustrates disposing the second wafer on a carrier substrate and polishing a second substrate of the second wafer as part of a method of manufacturing a semiconductor device;

FIG. 5 illustrates providing a first layer, a second layer, and an insulating layer on the second substrate of the second wafer as part of a method of manufacturing a semiconductor device;

FIG. 6 illustrates bonding the first water and the second wafer and removing the carrier substrate as part of a method of manufacturing a semiconductor device;

FIG. 7 illustrates bonding a third wafer including a cell area to the second wafer as part of a method of manufacturing a semiconductor device;

FIG. 8 is a diagram schematically illustrating an electronic system including a semiconductor device; and

FIG. 9 is a perspective view schematically illustrating an electronic system including a semiconductor device.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one component from another component, and the nature, the sequences, or the orders of the components are not limited by the terms. It should be noted that if one component is described as being “electrically connected,” “coupled” or “joined” to another component, the former may be directly “electrically connected,” “coupled,” and “joined” to the latter or “electrically connected”, “coupled”, and “joined” to the latter via another component.

The same name may be used to describe an element included in the embodiments described above and an element having a common function. Unless otherwise mentioned, the descriptions of the examples may be applicable to the following examples and thus, duplicated descriptions will be omitted for conciseness.

As used herein, the terms “substantially”, “approximately”, “generally”, and “about” in reference to a given parameter, property, or condition may include a degree that one of ordinary skill in the art would understand that the given parameter, property, or condition is met with a small degree of variance, such as within acceptable manufacturing tolerances. For example, a parameter that is substantially met may be at least 90% met, at least 95% met, or at least 99% met.

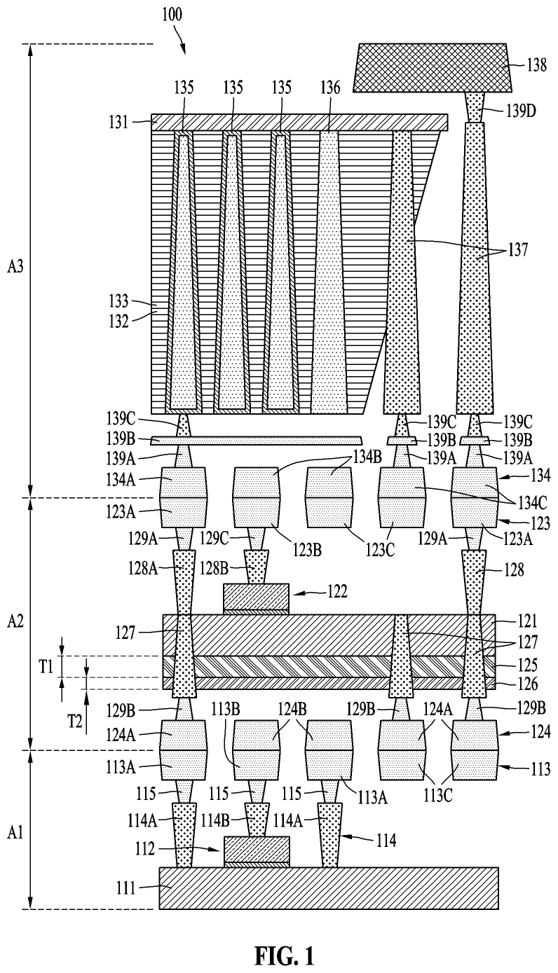

FIG. 1 is a diagram of a semiconductor device.

Referring to FIG. 1, a semiconductor device 100 may have a structure in which a plurality of device areas A1, A2, and A3 are bonded to each other and stacked. The bonded and stacked structure of the plurality of device areas A1, A2, and A3 may reduce the size of the semiconductor device 100.

The semiconductor device 100 may include a first peripheral circuit area A1. The first peripheral circuit area A1 may include a first substrate 111. The first peripheral circuit area A1 may include a first transistor 112 disposed on the first substrate 111. The first peripheral circuit area A1 may include a plurality of first bonding pads 113 disposed opposite the first substrate 111. The first peripheral circuit area A1 may include a plurality of first vias 114. At least one first via 114A among the plurality of first vias 114 may electrically connect the first substrate 111 and at least one first bonding pad 113A among the plurality of first bonding pads 113. Another first via 114B among the plurality of first vias 114 may electrically connect the first transistor 112 and another first bonding pad 113B among the plurality of first bonding pads 113. Among the plurality of first bonding pads 113, a predetermined first bonding pad 113C may not be electrically connected to the first substrate 111 or the first transistor 112. The first peripheral circuit area A1 may include a plurality of first sub-bonding pads 115 electrically connecting the plurality of first vias 114 and the plurality of first bonding pads 113, respectively. The semiconductor device 100 may include a second peripheral circuit area A2 disposed on the first peripheral circuit area A1. The second peripheral circuit area A2 may include a second substrate 121. The second peripheral circuit area A2 may include a second transistor 122 disposed on the second substrate 121. The second transistor 122 may be electrically connected to at least one second bonding pad 123B among the plurality of second bonding pads 123. The second peripheral circuit area A2 may include a plurality of second bonding pads 123 disposed opposite the second substrate 121. The second peripheral circuit area A2 may include a plurality of third bonding pads 124 respectively bonded to the plurality of first bonding pads 113. The plurality of third bonding pads 124 may be disposed opposite the plurality of second bonding pads 123 with respect to the second substrate 121.

The semiconductor device 100 may include a first layer 125 configured to contain hydrogen. For example, the first layer 125 may contain hydrogen. The first layer 125 may be disposed on and in contact with one surface of the second substrate 121 that faces the first substrate 111. The first layer 125 may include at least one, or a combination, of high density plasma (HDP) oxide or tetraethoxysilane (TEOS). The first layer 125 may reduce the leakage current of the semiconductor device 100 by contributing to the passivation of the second peripheral circuit area A2. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The semiconductor device 100 may include a second layer 126 configured to prevent diffusion of hydrogen from the first layer 125. The second layer 126 may be disposed on and in contact with one surface of the first layer 125 that faces the first substrate 111. For example, the second layer 126 may be disposed between the first layer 125 and the first substrate 111. The second layer 126 may include at least one, or a combination, of silicon nitride, zirconium oxide, or aluminum oxide. The second layer 126 may reduce or prevent diffusion of hydrogen from the first layer 125 in an undesired direction, thereby enhancing the passivation of the first layer 125 and reducing the leakage current of the semiconductor device 100.

The second peripheral circuit area A2 may include a plurality of through vias 127, which extend into (e.g., penetrate) the second layer 126, the first layer 125, and the second substrate 121. The height from the first substrate 111 to a first surface of a through via 127 facing the first substrate 111 may be substantially equal to or less than the height from the first substrate 111 to the second layer 126. For example, a first surface of the through vias 127 may be substantially coplanar with the surface of the through via 127 facing the first substrate 111. The gap between the second layer 126 and the third bonding pad 124 may be substantially equal to or greater than the gap between the surface of the through via 127 facing the first substrate 111 and the third bonding pad 124. This may improve the connectivity of the through via 127.

A thickness T1 of the first layer 125 may be substantially equal to or greater than a thickness T2 of the second layer 126. For example, a relatively greater thickness T1 of the first layer 125 may enhance passivation of the second peripheral circuit area A2 and a relatively smaller thickness T2 of the second layer 126 may reduce the size of the semiconductor device 100.

Each of the plurality of through vias 127 may have a width that decreases in a direction from the second layer 126 toward the second substrate 121. Although the implementation of the plurality of through vias 127 may increase the difficulty in manufacturing the semiconductor device 100, defects in devices such as transistors may be reduced while passivation of the peripheral circuit areas may be enhanced.

The second peripheral circuit area A2 may include a plurality of second vias 128. At least one second via 128A among the plurality of second vias 128 may electrically connect the plurality of second bonding pads 123 and the plurality of through vias 127, respectively. Each of the plurality of second vias 128A may have a width that decreases in a direction from the second bonding pad 123 toward the second substrate 121.

The semiconductor device 100 may include a second sub-bonding pad 129A bonding at least one second bonding pad 123A among the plurality of second bonding pads 123 and a corresponding second via 128A. At least one second bonding pad 123B among the plurality of second bonding pads 123 may be electrically connected to the second transistor 122 through the third via 128B and a third sub-bonding pad 129C. At least one second bonding pad 123C among the plurality of second bonding pads 123 may not be electrically connected to the second transistor 122, the through via 127, or the second via 128A.

The semiconductor device 100 may include a fourth sub-bonding pad 129B electrically connecting at least one third bonding pad 124A among the plurality of third bonding pads 124 and a corresponding through via 127. Among the plurality of third bonding pads 124, a predetermined third bonding pad 124B may not be electrically connected to the through via 127.

The semiconductor device 100 may include a cell area A3 disposed on the second peripheral circuit area A2. The cell area A3 may include a third substrate 131. The cell area A3 may include a plurality of gate electrodes 132 and a plurality of insulating layers 133 that are alternately stacked on the third substrate 131. The cell area A3 may include a plurality of fourth bonding pads 134 disposed opposite the third substrate 131. Among the plurality of fourth bonding pads 134, at least one fourth bonding pad 134A may be bonded to a second bonding pad 123A that is electrically connected to the second via 128A, and another fourth bonding pad 134B may be bonded to a second bonding pad 123C that is not electrically connected to any device. As illustrated in FIG. 1, one fourth bonding pad 134B may be bonded to the second bonding pad 123B.

The cell area A3 may include a plurality of first through structures 135 penetrating through the plurality of gate electrodes 132 and the plurality of insulating layers 133. The plurality of first through structures 135 may be electrically connected to the third substrate 131. Among the plurality of first through structures 135, at least one through structure 135 may be electrically connected to at least one fourth bonding pad 134A, and another through structure 135 may not be electrically connected to any bonding pad. The cell area A3 may include a second through structure 136 penetrating through the plurality of gate electrodes 132 and the plurality of insulating layers 133. The second through structure 136 may be electrically connected to the third substrate 131. The second through structure 136 may include a structure and material different from those of the first through structure 135. The cell area A3 may include a plurality of fourth vias 137. At least one fourth via 137 among the plurality of fourth vias 137 may be electrically connected to at least one fourth bonding pad 134C among the plurality of fourth bonding pads 134, penetrate through at least some gate electrodes 132 among the plurality of gate electrodes 132 and at least some insulating layers 133 among the plurality of insulating layers 133, and be electrically connected to the third substrate 131. Another fourth via 137 among the plurality of fourth vias 137 may be electrically connected to at least one fourth bonding pad 134C and an input/output pad 138. The cell area A3 may include the input/output pad 138 disposed on the third substrate 131.

The cell area A3 may include a plurality of fifth sub-bonding pads 139A. Among the plurality of fifth sub-bonding pads 139A, at least one fifth sub-bonding pad 139A may be electrically connected to the first through structure 135, and another fifth sub-bonding pad 139A may be electrically connected to the fourth via 137.

The cell area A3 may include a plurality of sixth sub-bonding pads 139B. At least one sixth sub-bonding pad 139B among the plurality of sixth sub-bonding pads 139B may be bonded to the fifth sub-bonding pad 139A and extend in a plane direction of the third substrate 131. Another sixth sub-bonding pad 139B among the plurality of sixth sub-bonding pads 139B may be electrically connected to a fifth sub-bonding pad 139A that is electrically connected to the fourth via 137.

The cell area A3 may include a plurality of seventh sub-bonding pads 139C. Among the plurality of seventh sub-bonding pads 139C, at least one seventh sub-bonding pad 139C may bond the extending sixth sub-bonding pad 139B and at least one first through structure 135, and the other seventh bonding pads 139C may bond the other sixth sub-bonding pads 139B and the plurality of fourth vias 137.

The cell area A3 may include an eighth sub-bonding pad 139D. The eighth sub-bonding pad 139D may bond a fourth via 137 not penetrating through the plurality of gate electrodes 132 and the plurality of insulating layers 133 to the input/output pad 138.

Although not shown in the drawing, the first transistor 112 may be electrically connected to the second peripheral circuit area A2 and/or the cell area A3 through at least one bonding pad and at least one via. The second transistor 122 may be electrically connected to the cell area A3 through at least one bonding pad and at least one via.

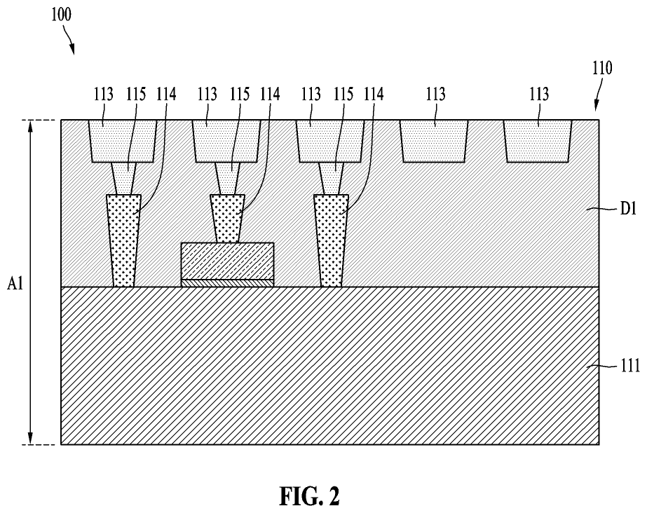

FIGS. 2 to 7 are diagrams illustrating a method of manufacturing a semiconductor device.

Referring to FIG. 2, a method of manufacturing the semiconductor device 100 may include providing a first wafer 110 having the first peripheral circuit area A1. The first wafer 110 may include the first substrate 111 and a first dielectric D1 on the first substrate 111. The first wafer 110 may include, in the first dielectric D1, the first transistor 112, the plurality of first bonding pads 113, the plurality of first vias 114, and the plurality of first sub-bonding pads 115.

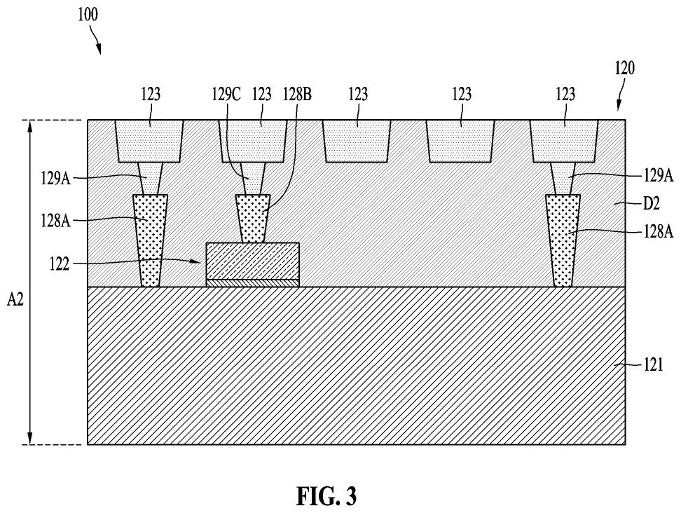

Referring to FIG. 3, the method of manufacturing the semiconductor device 100 may include providing a second wafer 120 having the second peripheral circuit area A2. The second wafer 120 may include the second substrate 121 and a second dielectric D2 on the second substrate 121. The second wafer 120 may include, in the second dielectric D1, the second transistor 122, the plurality of second bonding pads 123, the plurality of second vias 128A, at least one third via 128B, the plurality of second sub-bonding pads 129A, and at least one third sub-bonding pad 129C.

Meanwhile, although FIG. 2 is described first and FIG. 3 is described second, the method may include providing the second wafer 120 before providing the first wafer 110, or providing the first wafer 110 and the second wafer 120 substantially simultaneously.

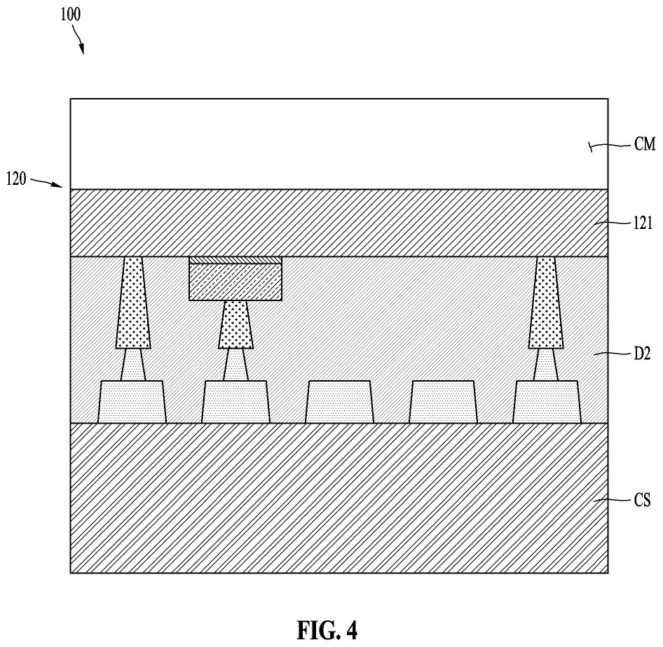

Referring to FIG. 4, the method of manufacturing the semiconductor device 100 may include flipping the second wafer 120. The method may include disposing the second dielectric D2 on the carrier substrate CS. The method may include polishing a portion CM of the second substrate 121.

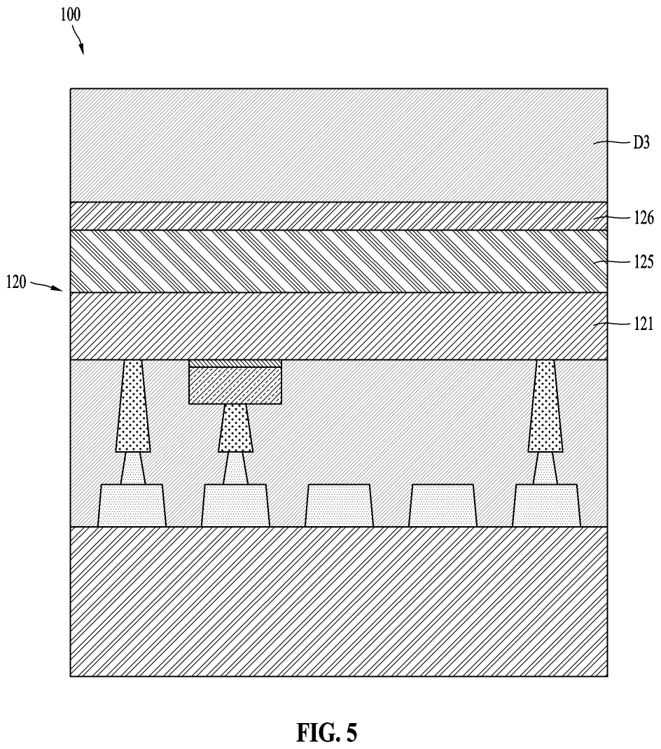

Referring to FIG. 5, the method of manufacturing the semiconductor device 100 may include depositing the first layer 125, the second layer 126, and the third dielectric D3 on the second substrate 121, which is the back side of the second wafer 120.

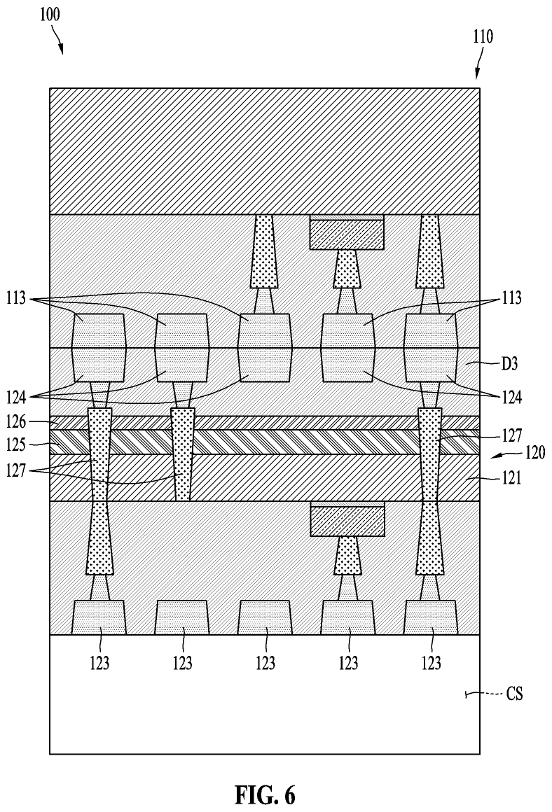

Referring to FIG. 6, the method of manufacturing the semiconductor device 100 may include flipping the first wafer 110. The method may include forming the plurality of third bonding pads 124 in the third dielectric D3. The method may include forming the plurality of vias 127 electrically connecting the second bonding pad 123 and the third bonding pad 124 and penetrating through each of the second substrate 121, the first layer 125, and the second layer 126. The method may include bonding the plurality of first bonding pads 113 and the plurality of third bonding pads 124. The method may include removing the carrier substrate CS from the second wafer 120.

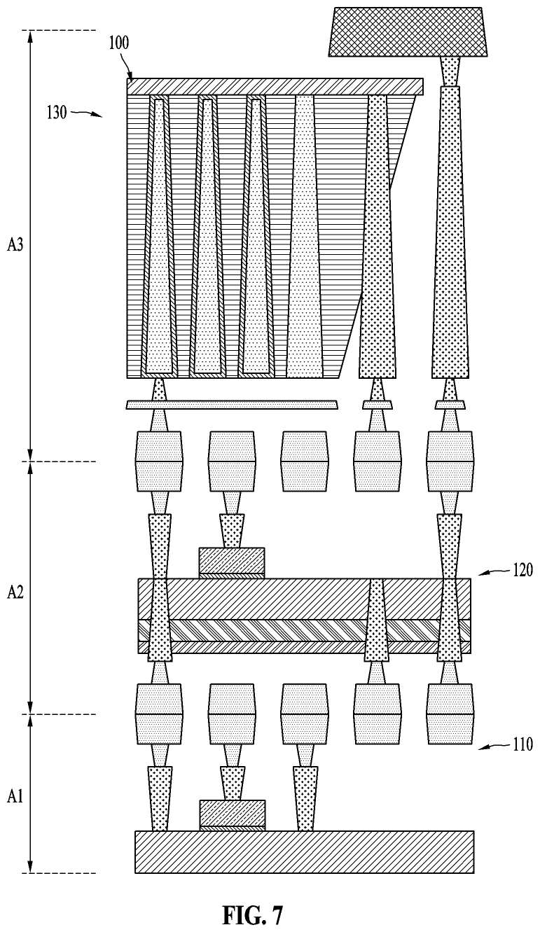

Referring to FIG. 7, the method of manufacturing the semiconductor device 100 may include flipping the first wafer 110 and the second wafer 120 so that the second peripheral circuit area A2 may be positioned on the first peripheral circuit area A1. The method may include bonding the third wafer 130 including the cell area A3 to the second wafer 120 so that the cell area A3 may be positioned on the second peripheral circuit area A2.

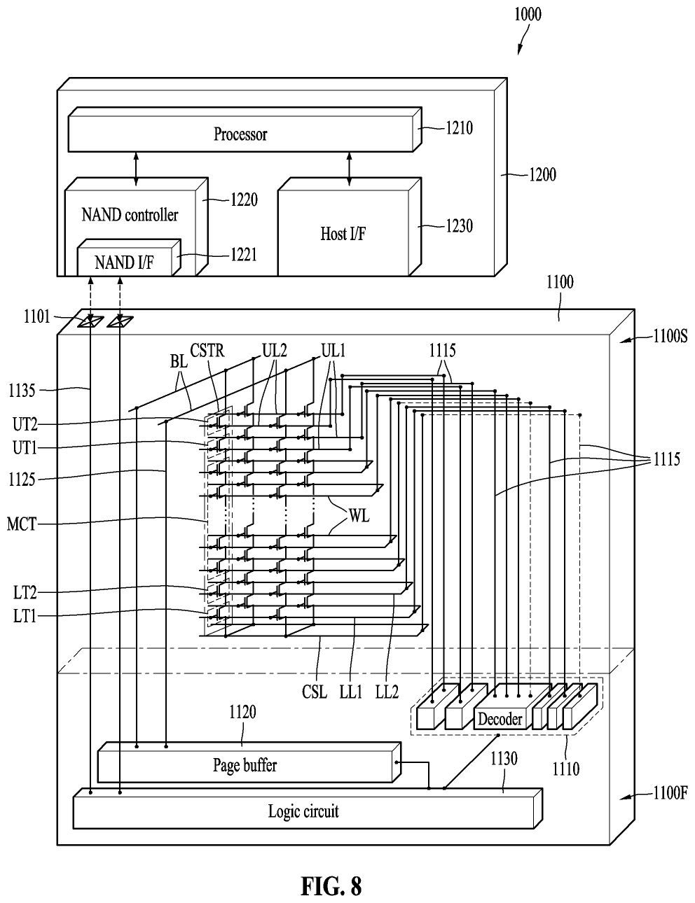

FIG. 8 is a diagram schematically illustrating an electronic system including a semiconductor device.

Referring to FIG. 8, an electronic system 1000 may include a semiconductor device 1100 and a controller 1200 electrically connected to the semiconductor device 1100. The semiconductor device 1100 may be the semiconductor device 100 described with reference to FIGS. 1 to 7. The electronic system 1000 may be a storage device including one or more semiconductor devices 1100 or an electronic device including the storage device. For example, the electronic system 1000 may be a solid-state drive (SSD) device, a Universal Serial Bus (USB), a computing system, a medical device, or a communication device, each of which includes one or more semiconductor devices 1100.

The semiconductor device 1100 may be a nonvolatile memory device, such as a NAND flash memory device. The semiconductor device 1100 may include a first structure 1100F and a second structure 1100S on the first structure 1100F. The first structure 1100F may include the first peripheral circuit area A1 and/or the second peripheral circuit area A2 described with reference to FIGS. 1 to 7. The second structure 1100S may include the cell area A3 described with reference to FIGS. 1 to 7.

The first structure 1100F may be a peripheral circuit structure that includes a decoder circuit 1110, a page buffer 1120, and a logic circuit 1130. The second structure 1100S may be a memory cell structure that includes bit lines BL, a common source line CSL, word lines WL, first gate upper lines UL1, second gate upper lines UL2, first gate lower lines LL1, second gate lower lines LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT between the lower transistors LT1 and LT2 and the upper transistors UT1 and UT2. The number of lower transistors LT1 and LT2 and the number of upper transistors UT1 and UT2 may vary.

The upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

The lower transistors LT1 and LT2 may include a lower erase control transistor LT1 and a ground selection transistor LT2 that are electrically connected in series. The upper transistors UT1 and UT2 may include a string selection transistor UT1 and an upper erase control transistor UT2 that are electrically connected in series. At least one of the lower erase control transistor LT1 and the upper erase control transistor UT2 may be used for an erasure operation of deleting data stored in the memory cell transistors MCT using a gate induced drain leakage (GIDL) phenomenon.

The common source line CSL, the first gate lower lines LL1, the second gate lower lines LL2, the word lines WL, the first gate upper lines UL1, and the second gate upper lines UL2 may be electrically connected to the decoder circuit 1110 through first connection wires 1115 that extend from the first structure 1100F to the second structure 1100S. The bit lines BL may be electrically connected to the page buffer 1120 through second connection wires 1125 that extend from the first structure 1100F to the second structure 1100S.

In the first structure 1100F, the decoder circuit 1110 and the page buffer 1120 may perform a control operation on at least one selection memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 that extends from the first structure 1100F to the second structure 1100S.

Although not shown in the drawings, the first structure 1100F may include a voltage generator (not shown). The voltage generator may generate a program voltage, a read voltage, a pass voltage, and a verification voltage required for the operation of the memory cell strings CSTR. Here, the program voltage may be a relatively high voltage (e.g., about 20 volts (V) to about 40 V) compared to the read voltage, the pass voltage, and the verification voltage.

The first structure 1100F may include high-voltage transistors and low-voltage transistors. The decoder circuit 1110 may include pass transistors electrically connected to the word lines WL of the memory cell strings CSTR. The pass transistors may include high-voltage transistors capable of withstanding high voltages such as the program voltage applied to the word lines WL in a program operation. The page buffer 1120 may also include high-voltage transistors capable of withstanding high voltages.

The controller 1200 may include a processor 1210, a NAND controller 1220, and a host interface 1230. The electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate based on predetermined firmware, and may control the NAND controller 1220 to access the semiconductor device 1100. The NAND controller 1220 may include a NAND interface 1221 that processes communication with the semiconductor device 1100. Through the NAND interface 1221, a control command to control the semiconductor device 1100, data to be written to the memory cell transistors MCT of the semiconductor device 1100, and/or data to be read from the memory cell transistors MCT of the semiconductor device 1100 may be transmitted. The host interface 1230 may provide a communication function between the electronic system 1000 and an external host. When a control command is received through the host interface 1230 from an external host, the processor 1210 may control the semiconductor device 1100 in response to the control command.

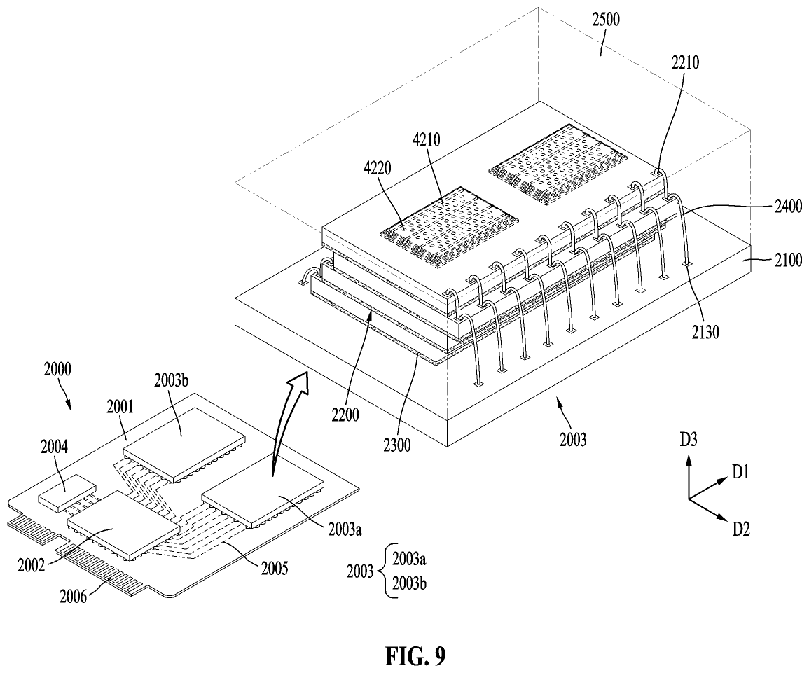

FIG. 9 is a perspective view schematically illustrating an electronic system including a semiconductor device.

Referring to FIG. 9, an electronic system 2000 may include a main board 2001, a controller 2002 disposed on the main board 2001, one or more semiconductor packages 2003, and a dynamic random-access memory (DRAM) 2004. The semiconductor packages 2003 and the DRAM 2004 may be electrically connected to the controller 2002 through wiring patterns 2005 formed on the main board 2001.

The main board 2001 may include a connector 2006 including a plurality of pins that are coupled to an external host. The number and arrangement of pins on the connector 2006 may vary based on a communication interface between the electronic system 2000 and the external host. The electronic system 2000 may communicate with the external host according to any one of the interfaces, for example, Universal Serial Bus (USB), Peripheral Component Interconnect Express (PCI Express), Serial Advanced Technology Attachment (SATA), or M-PHY for Universal Flash Storage (UFS). The electronic system 2000 may operate with the power supplied through the connector 2006 from the external host. The electronic system 2000 may further include a power management integrated circuit (PMIC) to distribute the power supplied from the external host to the controller 2002 and the semiconductor packages 2003.

The controller 2002 may be electrically connected to the semiconductor package 2003. The controller 2002 may write data to the semiconductor packages 2003 or read data from the semiconductor packages 2003, thereby increasing the operating speed of the electronic system 2000.

The DRAM 2004 may be a buffer memory to reduce the speed difference between the external host and the semiconductor packages 2003 that serve as data storage spaces. The DRAM 2004 included in the electronic system 2000 may operate as a kind of cache memory, and may provide a space for temporary data storage in a control operation on the semiconductor packages 2003. When the DRAM 2004 is included in the electronic system 2000, the controller 2002 may include not only a NAND controller for controlling the semiconductor packages 2003, but a DRAM controller for controlling the DRAM 2004.

The semiconductor package 2003 may include a first semiconductor package 2003a and a second semiconductor package 2003b that are spaced apart from each other. The first semiconductor package 2003a and the second semiconductor package 2003b may each be a semiconductor package including a plurality of semiconductor chips 2200. Each of the first semiconductor package 2003a and the second semiconductor package 2003b may include a package substrate 2100, semiconductor chips 2200 on the package substrate 2100, adhesion layers 2300 disposed on bottom surfaces of the semiconductor chips 2200, a connection structure 2400 that electrically connects the semiconductor chips 2200 to the package substrate 2100, and a molding layer 2500 that lies on the package substrate 2100 and covers the semiconductor chips 2200 and the connection structure 2400.

The package substrate 2100 may be a printed circuit board including upper pads 2130. Each of the semiconductor chips 2200 may include an input/output pad 2210. The input/output pad 2210 may correspond to the input/output pad 1101 of FIG. 8. Each of the semiconductor chips 2200 may include stacked structures 4210 and channel structures 4220. Each of the semiconductor chips 2200 may include the semiconductor device 100 described with reference to FIGS. 1 to 7.

The connection structure 2400 may be a bonding wire that electrically connects the input/output pad 2210 and the upper pads 2130. Therefore, in each of the first semiconductor package 2003a and the second semiconductor package 2003b, the semiconductor chips 2200 may be electrically connected to each other in a bonding wire manner, and may be electrically connected to the upper pads 2130 of the package substrate 2100. In each of the first semiconductor package 2003a and the second semiconductor package 2003b, the semiconductor chips 2200 may be electrically connected to each other through connection structures including through-silicon vias (TSVs) instead of the connection structures 2400 based on the bonding wire manner.

The controller 2002 and the semiconductor chips 2200 may be included in a single package. The controller 2002 and the semiconductor chips 2200 may be disposed on a separate interposer substrate other than the main board 2001, and the controller 2002 and the semiconductor chips 2200 may be electrically connected to each other through wires formed on the interposer substrate.

A number of embodiments have been described above. Nevertheless, it should be understood that various modifications and variations may be made to these embodiments. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and/or equivalents of the claims are within the scope of the following claims.

What is claimed is:

1. A semiconductor device comprising:
a first peripheral circuit area, the first peripheral circuit area comprising:
a first substrate;
a first bonding pad; and
a first via electrically connecting the first substrate and the first bonding pad;
a second peripheral circuit area disposed on the first peripheral circuit area, the second peripheral circuit area comprising:
a second substrate;
a second bonding pad;
a third bonding pad disposed opposite the second bonding pad;
a first layer disposed under the second substrate, the first layer comprising at least one, or a combination, of high density plasma oxide or tetraethoxysilane;
a second layer disposed under the first layer, the second layer comprising at least one, or a combination, of silicon nitride, zirconium oxide, or aluminum oxide; and
a through via penetrating through the second layer, the first layer, and the second substrate and electrically connecting the second bonding pad and the third bonding pad; and
a cell area disposed on the second peripheral circuit area.

2. The semiconductor device of claim 1, wherein a height from the first substrate to a surface of the through via facing the first substrate is equal to or less than a height from the first substrate to the second layer.

3. The semiconductor device of claim 1, wherein a gap between the second layer and the third bonding pad is equal to or greater than a gap between a surface of the through via facing the first substrate and the third bonding pad.

4. The semiconductor device of claim 1, wherein a thickness of the first layer is equal to or greater than a thickness of the second layer.

5. The semiconductor device of claim 1, wherein the through via has a width that decreases in a direction from the second layer toward the second substrate.

6. The semiconductor device of claim 1, wherein the second peripheral circuit area further comprises a second via electrically connecting the through via and the second bonding pad.

7. The semiconductor device of claim 6, wherein the second via has a width that decreases in a direction from the second bonding pad toward the second substrate.

8. The semiconductor device of claim 1, wherein the second peripheral circuit area further comprises:
a second transistor disposed on the second substrate;
an additional second bonding pad; and
a third via electrically connecting the additional second bonding pad and the second transistor.

9. The semiconductor device of claim 1, wherein the first peripheral circuit area further comprises:
a first transistor disposed on the first substrate;
an additional first bonding pad; and
an additional first via electrically connecting the additional first bonding pad and the first transistor.

10. The semiconductor device of claim 1, wherein the cell area comprises:
a third substrate; and
a plurality of gate electrodes and a plurality of second insulating layers that are alternately stacked on the third substrate.

11. A method of manufacturing a semiconductor device, the method comprising:
providing a first wafer comprising a first peripheral circuit area and a second wafer comprising a second peripheral circuit area, wherein the first peripheral circuit area comprises a first substrate, a first bonding pad, and a first via electrically connecting the first substrate and the first bonding pad, and the second peripheral circuit area comprises a second substrate and a second bonding pad;
providing a first layer disposed under the second substrate, the first layer comprising at least one, or a combination, of high density plasma oxide or tetraethoxysilane, and a second layer disposed under the first layer, the second layer comprising at least one, or a combination, of silicon nitride, zirconium oxide, or aluminum oxide;
providing a third bonding pad opposite the second bonding pad in the second peripheral circuit area, bonding the first bonding pad and the third bonding pad, and providing a through via electrically connecting the second bonding pad and the third bonding pad; and
bonding a third wafer comprising a cell area to the second peripheral circuit area.

12. The method of claim 11, further comprising:
flipping the second wafer before the providing of the first layer and the second layer.

13. The method of claim 11, further comprising:
disposing the second wafer on a carrier substrate before the providing of the first layer and the second layer.

14. The method of claim 13, further comprising:
removing the carrier substrate after the providing of the through via.

15. The method of claim 11, further comprising:
polishing the second substrate before the providing of the first layer and the second layer.

16. The method of claim 11, further comprising:
providing an insulating layer on the second layer after the providing of the first layer and the second layer.

17. The method of claim 11, further comprising:
flipping the first wafer and the second wafer before the bonding of the third wafer to the second peripheral circuit area.

18. The method of claim 11, wherein a height from the first substrate to a surface of the through via facing the first substrate is equal to or less than a height from the first substrate to the second layer.

19. The method of claim 11, wherein a gap between the second layer and the third bonding pad is equal to or greater than a gap between a surface of the through via facing the first substrate and the third bonding pad.

20. The method of claim 11, wherein a thickness of the first layer is equal to or greater than a thickness of the second layer.
